(19) United States
(12) Patent Application Publication
(10) Pub. No.: US 2008/0119049 A1
(43) Pub. Date: May 22, 2008

(54) PLASMA ETCHING METHOD AND APPARATUS

(75) Inventors: Doug Yong SUNG, Suwon-si (KR); Tae Yong Kwon, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/739,124

(22) Filed: Apr. 24, 2007

(30) Foreign Application Priority Data
Nov. 17, 2006 (KR) 2006-113959

(51) Int. Cl. C23F 1/00; H01L 21/302

(52) U.S. Cl. 438/689; 216/67; 156/345.43

(57) ABSTRACT

A plasma etching method and apparatus. In the plasma etching apparatus, pluralities of RF power supplies are respectively connected to upper and lower electrode via relevant matching networks to enable generation of various ion densities and ion energies of plasma by individually changing RF powers applied to the upper and lower electrodes through control of the RF power supplies, so that the plasma etching apparatus can perform all processes which includes a process requiring a low ion density and a low ion energy, a process requiring the low ion density and a high ion energy, a process requiring a high ion density and the low ion energy, and a process requiring the high ion density and the high ion energy, thereby realizing various plasma etching processes.

### CROSS-REFERENCE TO RELATED APPLICATIONS

This application claims priority under 35 U.S.A. §119(a) of Korean Patent Application No. 2006-0113959, filed on Nov. 17, 2006, in the Korean Intellectual Property Office, the disclosure of which is incorporated herein in its entirety by reference.

### BACKGROUND OF THE INVENTION

1. Field of the Invention

The present general inventive concept relates to a plasma etching method and apparatus, and, more particularly, to a plasma etching method and apparatus which can process semiconductor wafers with plasma.

2. Description of the Related Art

Generally, plasma refers to an ionized gas composed of positive ions, negative ions, electrons, excited atoms, molecules, chemically highly active radicals, etc. Since plasma has very different electrical and thermal properties from those of normal gases, it is also referred to as the fourth material state. As plasma includes ionized gas, it is usefully applied to semiconductor manufacturing processes, such as wafer etching, through chemical reaction or acceleration of the ionized gas by use of an electric field or a magnetic field.

Recently, plasma etching apparatuses employing high density plasma have been increasingly used for the semiconductor manufacturing process. This is attributable to the fact that such plasma etching apparatuses satisfy an increasing demand for large-diameter wafers in the current semiconductor industry while relieving incompatibility between the large-diameter wafers and requirements for fine processing of the wafers resulting from a current increasing degree of integration of the semiconductor devices.

Such plasma etching apparatuses can be generally classified into a capacitively coupled plasma (CCP) type and an inductively coupled plasma (ICP) type according to a manner of generating plasma.

Since the CCP apparatus has merit in that it can generate ions having high energy by use of a high electric field, the CCP apparatus is widely used in the art.

For example, the CCP etching apparatus includes an upper electrode and a lower electrode facing each other within a chamber. The upper electrode is connected to a first RF (radio frequency) power supply to apply a first RF power to the upper electrode, and the lower electrode is connected to a second RF power supply to apply a second RF power lower than the first RF power to the lower electrode. With this construction, an etching gas induced into the chamber becomes plasma by virtue of the first RF power applied to the upper electrode, and the plasma is induced into a wafer disposed on the lower electrode by the second RF power applied to the lower electrode to etch the wafer.

However, since the RF powers applied to the upper and lower electrodes via the RF power supplies have fixed magnitudes, both ion density and ion energy of the plasma are provided in fixed forms, respectively.

If the wafer as an etching target has a multilayer structure, each layer may require an ion density and ion energy different from other ion densities and ion energies associated with other layers to obtain optimal etching, causing difficulty in coping with change of uniformity caused by variation of the etching process.

### SUMMARY OF THE INVENTION

Therefore, it is an aspect of the general inventive concept to provide a plasma etching apparatus, which is configured to apply various RF powers to upper and lower electrodes at respective steps of a plasma etching process, generating various forms of ion density and ion energy.

Additional aspects and/or advantages of the present general inventive concept will be set forth in part in the description which follows and, in part, will be obvious from the description, or may be learned by practice of the present general inventive concept.

The foregoing and/or other aspects and utilities of the present general inventive concept may be achieved by providing a plasma etching apparatus to generate plasma within a chamber having an upper electrode and a lower electrode facing each other in the chamber and to perform plasma processing with respect to an etching target disposed on the lower electrode through application of RF power to the upper and lower electrodes, the plasma etching apparatus including a plurality of upper RF power supplies connected to the upper electrode to apply a first RF power to the upper electrode, a plurality of lower RF power supplies connected to the lower electrode to apply a second RF power to the lower electrode, a switch to individually turn on or off the plurality of upper and lower RF power supplies to adjust ion density and ion energy within the chamber, and a controller to control an operation of the switch to generate a specific ion density and a specific ion energy within the chamber.

The number of upper RF power supplies may be the same as the number of lower RF power supplies.

The number of upper RF power supplies may be more than the number of lower RF power supplies.

The number of lower RF power supplies may be more than the number of upper RF power supplies.

The plasma etching apparatus may further include an upper matching network connected between the upper electrode and the plurality of upper RF power supplies to match an impedance of the plurality of upper RF power supplies to an impedance of plasma within the chamber, and a lower matching network connected between the lower electrode and the plurality of lower RF power supplies to match an impedance of the plurality of lower RF power supplies to the impedance of the plasma within the chamber.

The first RF power applied to the upper electrode by the plurality of upper RF power supplies may be higher than the second RF power applied to the lower electrode by the plurality of lower RF supplies.

The foregoing and/or other aspects and utilities of the present general inventive concept may also be achieved by providing a plasma etching apparatus including upper and lower electrodes facing each other within a chamber, an etching target disposed on the lower electrode and having a multilayer structure, a plurality of upper RF power supplies to apply a first RF power to the upper electrode, a plurality of lower RF power supplies to apply a second RF power to the lower electrode, a switch to individually turn on or off each of the plurality of upper and lower RF power supplies to adjust ion density and ion energy within the chamber, and a controller to control an operation of the switch to sequentially generate specific ion densities and ion energies within the chamber in association with properties of respective layers of the etching target to optimally etch the respective layers.

The plasma etching apparatus may further include an upper matching network connected between the upper electrode and the plurality of upper RF power supplies to match an impedance of the plurality of upper RF power supplies to an impedance of plasma within the chamber, and a lower matching network connected between the lower electrode and the plurality of lower RF power supplies to match an impedance of the plurality of lower RF power supplies to the impedance of the plasma within the chamber.

The first RF power applied to the upper electrode by the plurality of upper RF power supplies may be higher than the second RF power applied to the lower electrode by the plurality of lower RF supplies.

The foregoing and/or other aspects and utilities of the present general inventive concept may also be achieved by providing a plasma etching apparatus to generate plasma within a chamber having a first electrode and a second electrode facing each other in the chamber and to perform plasma processing with respect to an etching target disposed on the second electrode through application of RF power to the first and second electrodes, the plasma etching apparatus including a first RF power supply to apply a first RF power to the first electrode; a second RF power supply to apply a second RF power to the first electrode, the second RF power being lower than the first RF power, a third RF power supply to apply a third RF power to the second electrode, the third RF power being lower than the second RF power, a fourth RF power supply to apply a fourth RF power to the second electrode, the fourth RF power being lower than the third RF power; a switch to individually turn on or off the first to fourth RF power supplies, and a controller to control an operation of the switch to vary the first to fourth RF powers applied to the first and second electrodes.

The plasma etching apparatus may further include a first matching network connected between the first electrode and the first and second RF power supplies to match an impedance of the first and second RF power supplies to an impedance of plasma within the chamber; and a second lower matching network connected between the second electrode and the third and fourth RF power supplies to match an impedance of the third and fourth RF power supplies to the impedance of the plasma within the chamber.

The controller may control the operation of the switch to generate a specific ion density and a specific ion energy within the chamber.

The etching target may have a multilayer structure, and the controller may control the operation of the switch to sequentially generate specific ion densities and specific ion energies within the chamber in association with properties of respective layers of the etching target to optimally etch respective layers.

The foregoing and/or other aspects and utilities of the present general inventive concept may also be achieved by providing a plasma etching method to generate plasma within a chamber, the chamber having an upper electrode and a lower electrode facing each other therein, and to perform plasma processing with respect to an etching target disposed on the lower electrode, the method including applying a first radio frequency (RF) power to the upper electrode with a plurality of upper RF power supplies connected to the upper electrode, applying a second radio frequency (RF) power to the lower electrode with a plurality of lower RF power supplies connected to the lower electrode, individually switching on or off the plurality of upper and lower RF power supplies to adjust ion density and ion energy within the chamber, and controlling the individual switching to generate a specific ion density and a specific ion energy within the chamber.

The foregoing and/or other aspects and utilities of the present general inventive concept may also be achieved by providing a method of plasma etching a wafer in a chamber, the chamber having an upper electrode and a lower electrode facing each other therein, the plasma etching method including loading a wafer onto a lower electrode in a chamber, etching a first layer of the wafer with plasma generated with a first predetermined ion density and a first predetermined ion energy in the chamber, and etching a second layer of the wafer with plasma generated with a second predetermined ion density and a second predetermined ion energy in the chamber.

The foregoing and/or other aspects and utilities of the present general inventive concept may also be achieved by providing a method of plasma etching a wafer in a chamber, the chamber having an upper electrode and a lower electrode facing each other therein, the plasma etching method including loading a wafer onto a lower electrode in a chamber, applying a first radio frequency (RF) power to an upper electrode with a plurality of upper RF power supplies connected to the upper electrode, applying a second radio frequency (RF) power to the lower electrode with a plurality of lower RF power supplies connected to the lower electrode, and sequentially controlling a switching on or off of the plurality of upper and lower RF power supplies to adjust ion density and ion energy within the chamber to etch a plurality of layers of the wafer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings, of which:

FIG. 1 is a schematic construction view illustrating a plasma etching apparatus in accordance with an embodiment of the present general inventive concept;

FIG. 2 is a graph illustrating process windows which can be obtained by the plasma etching apparatus of FIG. 1;

FIG. 3 is a cross-sectional view illustrating a layer structure of a wafer used in the plasma etching apparatus of FIG. 1;

FIG. 4 is a flow chart illustrating a process of etching a wafer by the plasma etching apparatus of FIG. 1;

FIG. 5 is a schematic construction view illustrating a plasma etching apparatus in accordance with another embodiment of the present general inventive concept; and

FIG. 6 is a schematic construction view illustrating a plasma etching apparatus in accordance with yet another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout the drawings. The embodiments are described below to explain the present general inventive concept by referring to the figures.

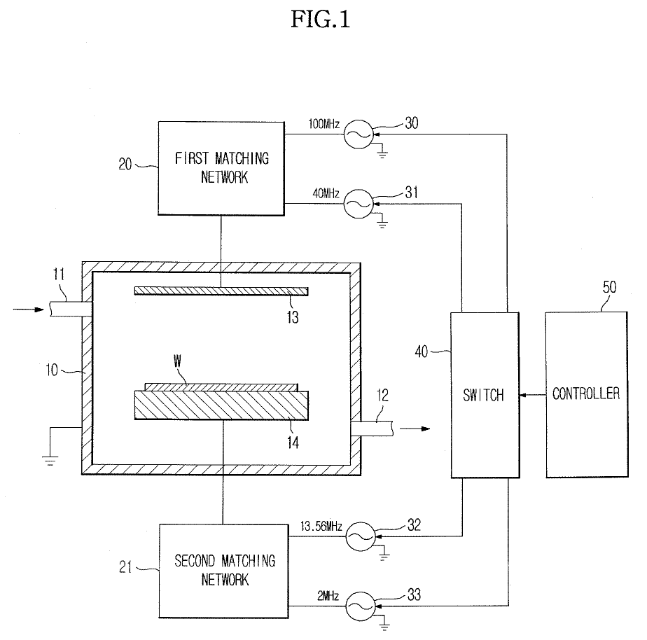

As illustrated in FIG. 1, the plasma etching apparatus according to an embodiment of the general inventive concept includes a chamber 10 that has a predetermined volume and is formed with a gas inlet 11 and a gas outlet 12. The chamber 10 is grounded. An etching gas is induced into the chamber 10 through the gas inlet 11, and discharged from the chamber 10 to an outside through the gas outlet 12.

The chamber 10 has an upper electrode 13 and a lower electrode 14 facing each other therein. The upper and lower electrodes 13 and 14 are formed from a conductive material, and have a planar shape. The lower electrode 14 also serves to hold a wafer W. The wafer W preferably has a multilayer structure which is composed of a plurality of layers, each having different etching properties from one another. It is desirable that at least two layers be etched by providing ion density and ion energy to cause optimal etching in such a manner that at least one of the ion density and the ion energy of one layer is different from the corresponding value of the other.

The upper and lower electrodes 13 and 14 are connected to RF power supplies 30 to 33 through matching networks 20 and 21, respectively. The upper electrode 13 is connected to a first RF power supply 30 and a second RF power supply 31 through a first matching network 20, and the lower electrode 14 is connected to a third RF power supply 32 and a fourth RF power supply 33 through a second matching network 21. For example, the first RF power supply 30 serves to apply a first RF power of 100 MHz to the upper electrode 13, and the second RF power supply 31 serves to apply a second RF power of 40 MHz lower than the first RF power to the upper electrode 13. The third RF power supply 32 serves to apply a third RF power of 13.56 MHz lower than the second RF power to the lower electrode 14, and the forth RF power supply 32 serves to apply a fourth RF power of 2 MHz lower than the third RF power to the lower electrode 14. For reference, since a frequency of RF power is in proportion to an ion density of plasma, and out of proportion to an ion energy thereof, an increase of the frequency causes an increase of the ion density of plasma within the chamber 10, and a decrease of the ion energy thereof within the chamber 10. Accordingly, it is possible to increase the ion density of the plasma through application of a higher frequency to the upper electrode 13, and to increase the ion energy within the chamber 10 through application of a lower frequency to the lower electrode 14.

The first matching network 20 serves to match an impedance of the first RF power supply 30 or the second RF power supply 31 to an impedance of the plasma within the chamber 10. The first matching network 20 is connected to the first and second RF power supplies 30 and 31 via a high frequency cable. In addition, the first matching network 20 is configured to allow the RF power singularly supplied from one of the first and second RF power supplies 30 and 31 to be applied in a singular form to an interior of the chamber 10 or to allow RF powers simultaneously supplied from both first and second RF power supplies 30 and 31 to be applied in a superimposed form to the interior of the chamber 10. At this time, unlike a case where the frequency is applied in the singular form, it is possible to adjust a ratio of the ion density to a density of neutral species through adjustment of a power ratio of a first frequency to a second frequency when the first and second RF powers from the respective first and second power supplies are simultaneously applied in a superimposed form. For example, when increasing the first RF power in comparison to an increasing degree of the second RF power, the ion density is increased in comparison to the density of the neutral species, thereby making it conducive to perform an anisotropic etching process. And, when increasing the second RF power in comparison to an increasing degree of the first RF power, the density of the neutral species is increased in comparison to the ion density, so that pattern damage caused by ion bombardment is reduced during the etching process. Furthermore, the first matching network 20 serves to prevent a reverse movement of RF power. For example, when the second RF power is superimposed on the first RF power, the first matching network prevents the first RF power or a wave thereof reflected by the second RF power from being directed to the second RF power supply 31.

As in the first matching network 20, the second matching network 21 serves to match the impedance of the third RF power supply 32 or the fourth RF power supply 33 to the impedance of the plasma within the chamber 10. The second matching network 21 is connected to the third and fourth RF power supplies 32 and 33 via a high frequency cable. In addition, the second matching network 21 is configured to allow the RF power singularly supplied from one of the third and fourth RF power supplies 32 and 33 to be applied in a singular form to the interior of the chamber 10 or to allow the RF powers simultaneously supplied from both the third and fourth RF power supplies 32 and 33 to be applied in a superimposed form to the interior of the chamber 10. At this time, when the third RF power is superimposed on the fourth RF power, it is possible to obtain an ion energy having a frequency in an intermediate band higher than in the case of applying the third RF power of 13.56 MHz and lower than in the case of applying the fourth RF power of 2 MHz. Furthermore, the second matching network 21 serves to prevent a reverse movement of the RF power. For example, when the fourth RF power from the fourth RF power supply 33 is modified with the third RF power from the third RF power supply 32, the second matching network 21 prevents the third RF power or a reflected wave of the fourth RF power from being directed to the fourth RF power supply 32.

The first to fourth RF power supplies 30, 31, 32, and 33 are connected to a switch 40 via signal cables, respectively.

The switch 40 individually turns on or off the first to fourth RF power supplies 30 to 33 to adjust the first to fourth RF powers applied to the upper electrode 13 and the lower electrode 14. With this construction, it is possible to adjust the ion density and the ion energy within the chamber 10.

The controller 50 controls operation of the switch 40 to individually vary the first to fourth RF powers applied to the upper and lower electrodes 13 and 14 in real time in such a way that at least one of the first to fourth RF powers or superimposed RF powers of a first RF power RF1, a second RF power RF2, a third RF power RF3, and a fourth RF power RF4 is or are applied to the upper electrode 13 and the lower electrode 14 via the switch 40 at each step of the plasma etching process, so that the ion density and the ion energy of plasma are realized in various forms, thereby ensuring various plasma etching processes.

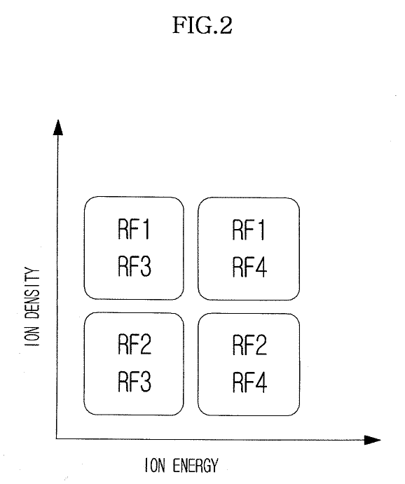

From process windows as illustrated in FIG. 2, it can be understood that an increase of RF power applied to the upper electrode 13 from the second RF power RF2 to the first RF power RF1 results in an increase of the ion density of plasma, whereas reduction of the RF power applied thereto from the first RF power RF1 to the second RF power RF2 results in reduction of the ion density. Furthermore, it can be understood that reduction of the RF power applied to the lower electrode 14 from the third RF power RF3 to the fourth RF power RF4 results in an increase of the ion energy, whereas an increase of the RF power applied to the lower electrode 14 from the fourth RF power RF4 to the third RF power RF3 results in reduction of the ion energy. Accordingly, it is possible to realize various plasma etching processes through generation of specific ion density and ion energy by use of such an operation. In other words, it is possible to realize the various plasma etching processes that include a process RF2+RF3 requiring a low ion density and a low ion energy, a process RF2+RF4 requiring the low ion density and a high ion energy, a process RF1+RF3 requiring a high ion density and the low ion energy, and a process RF1+RF4 requiring the high ion density and the high ion energy. Meanwhile, the controller 50 may include a memory that stores information of RF power outputs corresponding to respective layers of the wafer to generate the ion density and ion energy to optimally etch the respective layers.

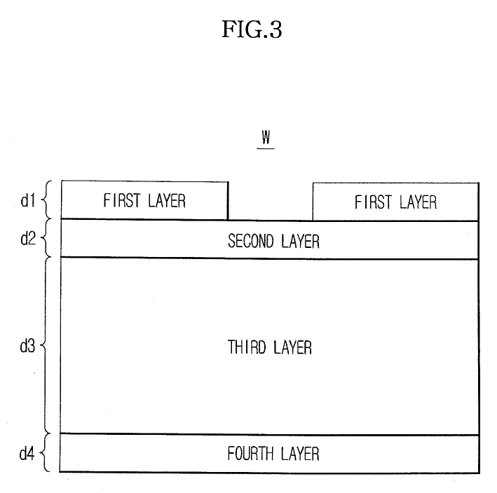

Referring to FIG. 3, one example of the wafer W processed by the plasma etching apparatus according to the embodiment is illustrated. The wafer W is constituted by a four-layer structure having a predetermined thickness (d1+d2+d3+d4), in which all the four layers of the wafer are etching targets, and different in ion density and ion energy to perform optimal etching and ensure uniformity of the respective layers. For example, a first layer permits the optimal etching with a low ion density and a low ion energy, a second layer permits the optimal etching with the low ion density and a high ion energy, a third layer permits the optimal etching with a high ion density and the low ion energy, and a fourth layer permits the optimal etching with the high ion density and the high ion energy. Of course, the respective layers may be superimposed on one another. For the wafer W, therefore, it is possible to obtain an optimal result of the etching process through generation of plasma having different properties corresponding to the respective layers.

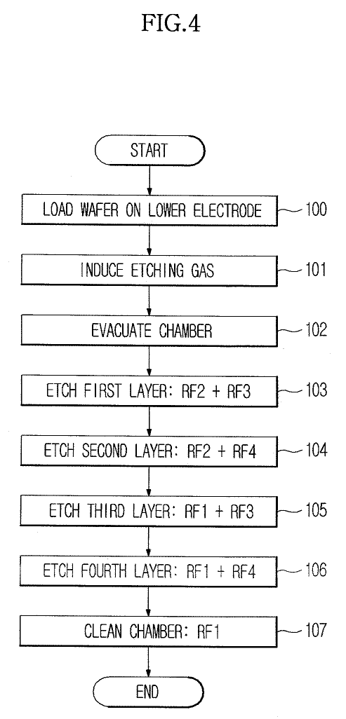

Referring to FIG. 4, an operation of the plasma etching apparatus according to the embodiment will be described hereinafter. First, the wafer W is mounted on the lower electrode 14 at operation 100, followed by inducing an etching gas into the chamber 10 at operation 101. The chamber 10 is evacuated to vacuum at operation 102.

In this state, at operation 103, a second RF power is applied to the upper electrode 13 while a third RF power is applied to the lower electrode 14 by turning on only the second and third RF power supplies 31 and 32 to generate a low ion density and a low ion energy within the chamber 10, etching a first layer of the wafer W. In other words, free electrons are emitted from the upper electrode 13 by an electric field created between the upper electrode 13 and the lower electrode 14, and accelerated with a kinetic energy caused by the electric field to pass through the etching gas within the chamber 10 while impinging against the etching gas, transferring the energy to the etching gas. The etching gas supplied with the energy is then ionized to form ions, which are also accelerated with a kinetic energy caused by the electric field to pass through the etching gas within the chamber 10 while impinging against the etching gas, transferring the energy to the etching gas. With such repetitious reactions between the etching gas and the electric field, plasma having a low ion density is created within the chamber 10, and uniformly enters the first layer with use of the low ion energy, thereby etching the first layer of the wafer W.

After etching the first layer, at operation 104, the second RF power is applied to the upper electrode 13 while a forth RF power is applied to the lower electrode 14 by turning on only the second and fourth RF power supplies 31 and 33 to generate the low ion density and a high ion energy within the chamber 10, etching a second layer of the wafer W. In other words, plasma having the low ion density is created within the chamber 10, and uniformly enters the second layer with use of the high ion energy, thereby etching the second layer of the wafer W.

After etching the second layer, at operation 105, the first RF power is applied to the upper electrode 13 while the third RF power is applied to the lower electrode 14 by turning on only the first and third RF power supplies 30 and 32 to generate a high ion density and the low ion energy within the chamber 10, etching a third layer of the wafer W. In other words, plasma having the high ion density is created within the chamber 10, and uniformly enters the third layer with use of the low ion energy, thereby etching the third layer of the wafer W.

After etching the third layer, at operation 106, the first RF power is applied to the upper electrode 13 while the fourth RF power is applied to the lower electrode 14 by turning on only the first and fourth RF power supplies 30 and 33 to generate the high ion density and the high ion energy within the chamber 10, etching a fourth layer of the wafer W. In other words, plasma having the high ion density is created within the chamber 10, and uniformly enters the fourth layer with use of the high ion energy, thereby etching the fourth layer of the wafer W.

After etching the fourth layer, at operation 107, the first RF power is applied to the upper electrode 13 by turning on only the first RF power supply 30 to generate the high ion density within the chamber 10, cleaning the chamber 10.

After cleaning the chamber 10, the etching process of the wafer W is completed.

In this way, since the plasma etching apparatus of the general inventive concept can adjust the ion density and the ion energy to ensure the optimal etching of the respective layers of the wafer W, it is possible to etch the respective layers at a high etching rate without damage.

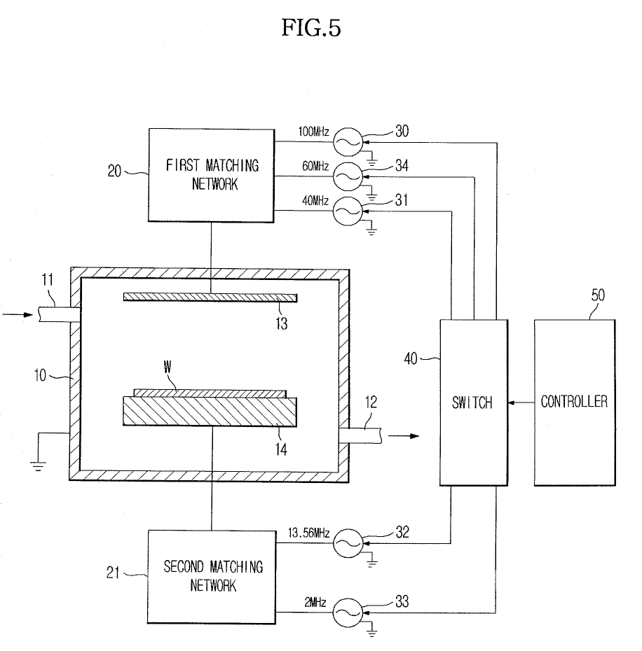

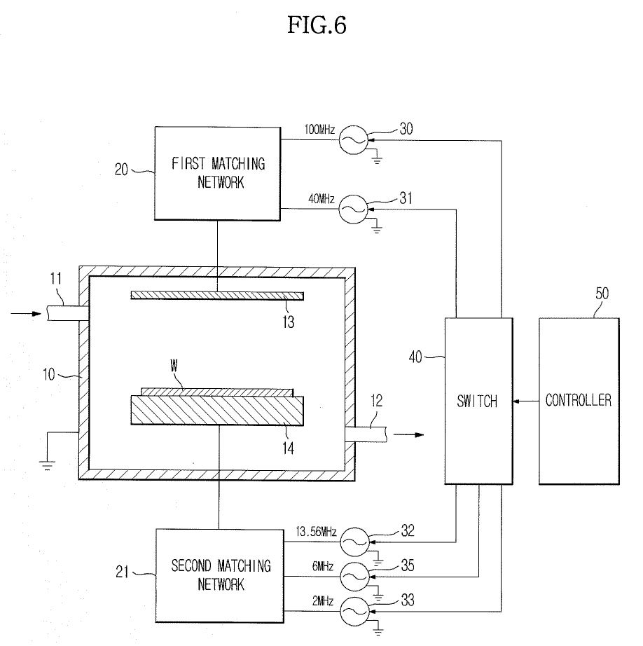

The above embodiment is described with two RF power supplies being connected to each of the upper and lower electrodes 13 and 14. However, it should be noted that the present general inventive concept is not limited to this construction. Alternatively, three or more RF power supplies may be connected to each of the upper and lower electrodes. Furthermore, although the above embodiment is described as having a same number of RF power supplies being connected to each of the upper and lower electrodes 13 and 14, the present general inventive concept is not limited to this construction, and a number (3) of RF power supplies connected to the upper electrode 13 may be more than a number (2) of RF power supplies connected to the lower electrode 14, as illustrated in FIG. 5. In this case, it is possible to more precisely adjust the ion density than the ion energy. Alternatively, a number (3) of RF power supplies connected to the lower electrode 14 may be more than a number (2) of RF power supplies connected to the upper electrode 13, as illustrated in FIG. 6. In this case, it is possible to more precisely adjust the ion energy than the ion density.

As apparent from the above description, in the plasma etching apparatus according to the general inventive concept, pluralities of RF power supplies are respectively connected to upper and lower electrodes via relevant matching networks to enable generation of various ion densities and ion energies of plasma by individually changing RF powers applied to the upper and lower electrodes through control of the pluralities of RF power supplies, so that the plasma etching apparatus can perform all processes which include a process with a low ion density and a low ion energy, a process with the low ion density and a high ion energy, a process with a high ion density and the low ion energy, and a process with the high ion density and the high ion energy, thereby realizing various plasma etching processes.

Although a few embodiments of the present general inventive concept have been illustrated and described, it would be appreciated by those skilled in the art that changes may be made in these embodiments without departing from the principles and spirit of the general inventive concept, the scope of which is defined in the claims and their equivalents.

What is claimed is:

1. A plasma etching apparatus to generate plasma within a chamber having an upper electrode and a lower electrode facing each other in the chamber and to perform plasma processing with respect to an etching target disposed on the lower electrode through application of RF power to the upper and lower electrodes, the apparatus comprising:
a plurality of upper RF power supplies connected to the upper electrode to apply a first RF power to the upper electrode;
a plurality of lower RF power supplies connected to the lower electrode to apply a second RF power to the lower electrode;
a switch to individually turn on or off the plurality of upper and lower RF power supplies to adjust ion density and ion energy within the chamber; and
a controller to control an operation of the switch to generate a specific ion density and a specific ion energy within the chamber.

2. The apparatus according to claim 1, wherein the number of upper RF power supplies is the same as the number of the lower RF power supplies.

3. The apparatus according to claim 1, wherein the number of upper RF power supplies is more than the number of lower RF power supplies.

4. The apparatus according to claim 1, wherein the number of lower RF power supplies is more than the number of upper RF power supplies.

5. The apparatus according to claim 1, further comprising:
an upper matching network connected between the upper electrode and the plurality of upper RF power supplies to match an impedance of the plurality of upper RF power supplies to an impedance of plasma within the chamber; and
a lower matching network connected between the lower electrode and the plurality of lower RF power supplies to match an impedance of the plurality of lower RF power supplies to the impedance of the plasma within the chamber.

6. The apparatus according to claim 1, wherein the first RF power applied to the upper electrode by the plurality of upper RF power supplies is higher than the second RF power applied to the lower electrode by the plurality of lower RF supplies.

7. A plasma etching apparatus, comprising:
upper and lower electrodes facing each other within a chamber;
an etching target disposed on the lower electrode and having a multilayer structure;
a plurality of upper RF power supplies to apply a first RF power to the upper electrode;
a plurality of lower RF power supplies to apply a second RF power to the lower electrode;
a switch to individually turn on or off each of the plurality of upper and lower RF power supplies to adjust ion density and ion energy within the chamber; and
a controller to control an operation of the switch to sequentially generate specific ion densities and ion energies within the chamber in association with properties of respective layers of the etching target to optimally etch the respective layers.

8. The apparatus according to claim 7, further comprising:
an upper matching network connected between the upper electrode and the plurality of upper RF power supplies to match an impedance of the plurality of upper RF power supplies to an impedance of plasma within the chamber; and
a lower matching network connected between the lower electrode and the plurality of lower RF power supplies to match an impedance of the plurality of lower RF power supplies to the impedance of the plasma within the chamber.

9. The apparatus according to claim 7, wherein the first RF power applied to the upper electrode by the plurality of upper RF power supplies is higher than the second RF power applied to the lower electrode by the plurality of lower RF supplies.

10. A plasma etching apparatus to generate plasma within a chamber having a first electrode and a second electrode facing each other in the chamber and to perform plasma processing with respect to an etching target disposed on the second electrode through application of RF power to the first and second electrodes, the plasma etching apparatus comprising:
a first RF power supply to apply a first RF power to the first electrode;
a second RF power supply to apply a second RF power to the first electrode, the second RF power being lower than the first RF power;
a third RF power supply to apply a third RF power to the second electrode, the third RF power being lower than the second RF power;
a fourth RF power supply to apply a fourth RF power to the second electrode, the fourth RF power being lower than the third RF power;
a switch to individually turn on or off the first to fourth RF power supplies; and
a controller to control an operation of the switch to vary the first to fourth RF powers applied to the first and second electrodes.

11. The apparatus according to claim 10, further comprising:
a first matching network connected between the first electrode and the first and second RF power supplies to match an impedance of the first and second RF power supplies to an impedance of plasma within the chamber; and
a second matching network connected between the second electrode and the third and fourth RF power supplies to match an impedance of the third and fourth RF power supplies to the impedance of the plasma within the chamber.

12. The apparatus according to claim 10, wherein the controller controls operation of the switch to generate a specific ion density and a specific ion energy within the chamber.

13. The apparatus according to claim 10, wherein the etching target has a multilayer structure, and the controller controls the operation of the switch to sequentially generate specific ion densities and specific ion energies within the chamber in association with properties of respective layers of the etching target to optimally etch the respective layers.

14. A plasma etching method to generate plasma within a chamber, the chamber having an upper electrode and a lower electrode facing each other therein, and to perform plasma processing with respect to an etching target disposed on the lower electrode, the method comprising:
applying a first radio frequency (RF) power to the upper electrode with a plurality of upper RF power supplies connected to the upper electrode;
applying a second radio frequency (RF) power to the lower electrode with a plurality of lower RF power supplies connected to the lower electrode;
individually switching on or off the plurality of upper and lower RF power supplies to adjust ion density and ion energy within the chamber; and
controlling the individual switching to generate a specific ion density and a specific ion energy within the chamber.

15. The plasma etching method of claim 14, further comprising:
matching an impedance of the plurality of upper RF power supplies to an impedance of plasma within the chamber with an upper matching network connected between the upper electrode and the plurality of upper RF power supplies; and
matching an impedance of the plurality of lower RF power supplies to the impedance of the plasma within the chamber with a lower matching network connected between the lower electrode and the plurality of lower RF power supplies.

16. The plasma etching method of claim 14, wherein the first RF power applied to the upper electrode by the plurality of upper RF power supplies is higher than the second RF power applied to the lower electrode by the plurality of lower RF supplies.

17. The plasma etching method of claim 14, wherein the controlling the individual switching sequentially generates specific ion densities and ion energies within the chamber in association with properties of respective layers of the etching target to optimally etch the respective layers.

18. A method of plasma etching a wafer in a chamber, the chamber having an upper electrode and a lower electrode facing each other therein, the plasma etching method comprising:
loading a wafer onto a lower electrode in a chamber;
etching a first layer of the wafer with plasma generated with a first predetermined ion density and a first predetermined ion energy in the chamber; and
etching a second layer of the wafer with plasma generated with a second predetermined ion density and a second predetermined ion energy in the chamber.

19. The plasma etching method of claim 18, wherein the etching of the first layer and the etching of the second layer each comprise:
generating plasma to create a specific ion density and a specific ion energy on the wafer within the chamber.

20. The plasma etching method of claim 19, wherein the controlling comprises:
individually switching on or off a plurality of upper and lower RF power supplies to adjust ion density and ion energy within the chamber.

21. A method of plasma etching a wafer in a chamber, the chamber having an upper electrode and a lower electrode facing each other therein, the plasma etching method comprising:
loading a wafer onto a lower electrode in a chamber;
applying a first radio frequency (RF) power to an upper electrode with a plurality of upper RF power supplies connected to the upper electrode;
applying a second radio frequency (RF) power to the lower electrode with a plurality of lower RF power supplies connected to the lower electrode; and
sequentially controlling a switching on or off of the plurality of upper and lower RF power supplies to adjust ion density and ion energy within the chamber to etch a plurality of layers of the wafer.
